(19) United States
(12) Patent Application Publication
(10) Pub. No.: US 2009/0004384 A1
(43) Pub. Date: Jan. 1, 2009

(54) Processing Assembly and Method for Processing a Wafer in Such a Processing Assembly

(75) Inventor: Antonius M.C.P.L. Van De Kerkhof, Handel (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/278,881

(22) PCT Filed: Feb. 26, 2007
(86) PCT No.: PCT/IB2007/050608

§ 371 Date: Aug. 8, 2008

(30) Foreign Application Priority Data
Feb. 28, 2006 (EP) 06110513.6

(51) Int. Cl. C23C 16/00

(52) U.S. Cl. 427/248.1; 118/715

(57) ABSTRACT

Processing assembly comprising a processing chamber (2) adapted for receiving at least one wafer (5) to be processed, the processing assembly (1) further being provided with a pump (3) being connectable in fluid connection with the processing chamber (2) for maintaining the pressure in the processing chamber (2) in a low pressure range during processing, wherein the processing assembly (1) is provided with a second pump (4) being connectable in fluid connection with the processing chamber (2) for lowering the pressure from a relatively high pressure, e.g. atmospheric pressure, to the low pressure range, wherein gas flow in the processing chamber (2) during lowering the pressure has a constant value. The invention further relates to a method for processing a wafer (5) in such a processing assembly (1).

### FIELD OF THE INVENTION

The invention relates to a processing assembly comprising a processing chamber adapted for receiving at least one wafer to be processed, the processing assembly further being provided with a pump being connectable in fluid connection with the processing chamber for maintaining the pressure in the processing chamber in a low pressure range during processing, wherein the processing assembly is provided with a second pump being connectable in fluid connection with the processing chamber for lowering the pressure from a relatively high pressure, e.g. atmospheric pressure, to the low pressure range.

### BACKGROUND OF THE INVENTION

Such a processing assembly is known from EP 1,014,427. The known processing assembly comprises a processing chamber and is adapted to process a substrate in said processing chamber. The processing assembly further comprises an integrated pumping system having a pre-vacuum pump for evacuating gas from the processing chamber to obtain a low pressure in the processing chamber and a high vacuum pump to maintain the low pressure in the processing chamber during processing. The integrated pumping system is provided with a control for adjusting the pumping speed of the pre-vacuum pump. The control can be provided with a predetermined pressure profile to which the pumping speed is adjusted such that the pressure drop in the processing chamber follows that profile.

A disadvantage of such a known assembly is the occurrence of turbulence in the processing chamber while evacuating gas from said chamber. Due to said turbulence, small particles that are situated on the substrate or elsewhere in the processing chamber are released and are floating in the processing chamber with the risk of colliding with the substrate, thus contaminating and possibly damaging the substrate. This results in production losses and thus unnecessary costs and time.

### SUMMARY OF THE INVENTION

Therefore, the object of the invention is to provide a processing assembly for processing at least one wafer in a processing chamber, wherein damage caused by floating particles is minimized during decreasing the pressure in the processing chamber.

In order to achieve this object the processing assembly according to the invention is characterized in that gas flow in the processing chamber during lowering the pressure has a constant value. Due to a constant gas flow the occurrence of pressure pulses is minimized resulting in less turbulence during pumping down the pressure in the processing chamber. Less turbulence means fewer particles released and consequently less particles contaminating and damaging the wafers.

Preferably, the constant value of the gas flow is the product of pumping velocity of the second pump and the pressure in said processing chamber.

To obtain the fluent pressure drop in the processing room, the processing assembly is provided, according to an advantageous embodiment of the invention, with a control for controlling the first pump and the second pump. The control is able to switch between said pumps and to arrange the pumps being in fluid connection with the processing chamber when necessary.

According to a further elaboration of the invention, the pumping velocity of the second pump is adjustable by the control depending on the pressure in the processing chamber. To control the velocity of the second pump as a function of the pressure in the processing room provides a direct adjustment, such that the gas flow is prevented from showing fluctuations due to changes in pressure.

It is also possible that the control of the second pump is provided with a velocity profile. Such a velocity profile can be based on previously established evacuation behavior of said processing chamber, wherein it has been established with which velocity profile the flow is kept constant. In such an embodiment no pressure gauge or flow meter is necessary to obtain the constant flow required.

The invention further relates to a method for processing a wafer in an above mentioned processing assembly comprising a processing chamber, wherein a wafer to be processed is provided, wherein the processing assembly further comprises:

a first pump that is brought in fluid connection with the processing chamber to maintain pressure in the processing chamber in a low pressure range during processing, and

a second pump that is brought in fluid connection with the processing chamber before processing to pump down the pressure from a relatively high pressure, e.g. atmospheric pressure, to the low-pressure range in said chamber,

wherein during pumping down, the pumping velocity of the second pump is adjusted to provide a gas flow with a constant value in the processing chamber during pumping down.

This method for processing a wafer in a processing assembly provides the same kind of advantages that are described with the processing assembly.

### BRIEF DESCRIPTION OF THE DRAWINGS

The invention will be further elucidated by means of an exemplary embodiment with reference to the accompanying drawing in which:

FIG. 1 shows a schematic view of a processing assembly; and

FIG. 2 shows a diagram of the particle reduction with constant value of gas flow.

### DETAILED DESCRIPTION OF EMBODIMENTS

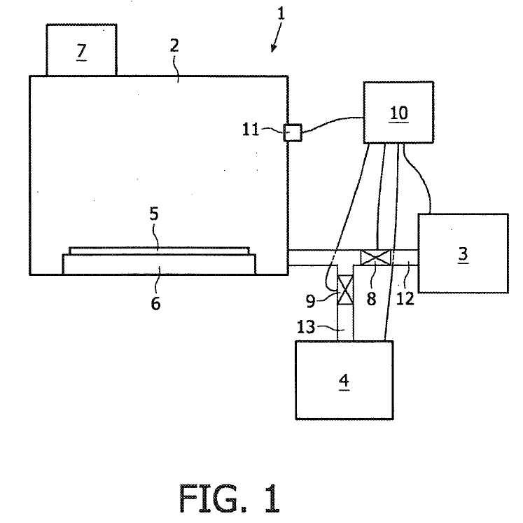

In FIG. 1 a schematic view of a processing assembly 1 according to the invention is shown. The processing assembly 1 comprises a processing chamber 2. In the processing chamber 2 a wafer 5 is provided to be processed. To the processing chamber 2 a process gas device 7 for processing the wafer 5 is connected. The processing assembly 1 further comprises two pumps 3, 4 being connectable in fluid connection with the processing chamber 2. A first pump 3 is adapted to maintain the pressure in the processing chamber 2 in a low-pressure range during processing. Said first pump 3 can be a process pump with a capacity in the range of 500 m3 and 1500 m3 per hour.

Before processing the wafer 5, the pressure in the processing chamber 2 is brought down from a relatively high pressure, e.g. atmospheric pressure, to a low-pressure range by a second pump 4. Said second pump 4 for instance can be a dry pump, with a capacity in the range of 10 m3 and 50 m3 per hour. The first pump 3 and second pump 4 are controlled by a control 10 that is provided in the processing assembly 1. The control 10 can adjust the pumping velocity of the second pump 4 depending on the pressure in the processing chamber 2. Therefore, the processing chamber 2 is provided with a pressure gauge 11 for measuring the pressure in said chamber 2. The pressure gauge 11 is able to generate a pressure signal that is send to the control 10. The processing assembly 1 is adapted to lower the pressure in the processing chamber 2 having a gas flow with a constant value in the processing chamber 2. Said gas flow value is represented by the following equation:

Q=S(p)×P,

wherein Q is the constant value of gas flow, S(p) is the pumping velocity of the second pump 4 and P is the pressure in the processing chamber 2.

After providing a wafer 5 in the processing room 2, the processing chamber is connected in fluid connection with the second pump 4 to lower the pressure from atmospheric pressure to a low-pressure range. The control 10 closes first valve 8 in pipe 12 and opens second valve 9 in pipe 13. The pump velocity is controlled by control 10 and can be adjusted if pressure gauge 11 sends a pressure signal to control 10 to maintain the constant gas flow value. When the low pressure in the processing chamber 2 is reached, the control 10 closes second valve 9 and opens first valve 8 and pump 3 maintains the pressure in the processing chamber 2 at the low pressure range at least until processing of wafer 5 has been finished. The value of the pressure in the processing chamber at which the first pump 3 takes over pumping from the second pump 4 preferably is a threshold value that is low enough to optimally avoid risk of turbulence in the processing chamber 2. Depending on this threshold value and the pressure that is required for a certain process, the first pump 4 can also be used to evacuate the last amount of gas from the processing chamber 2.

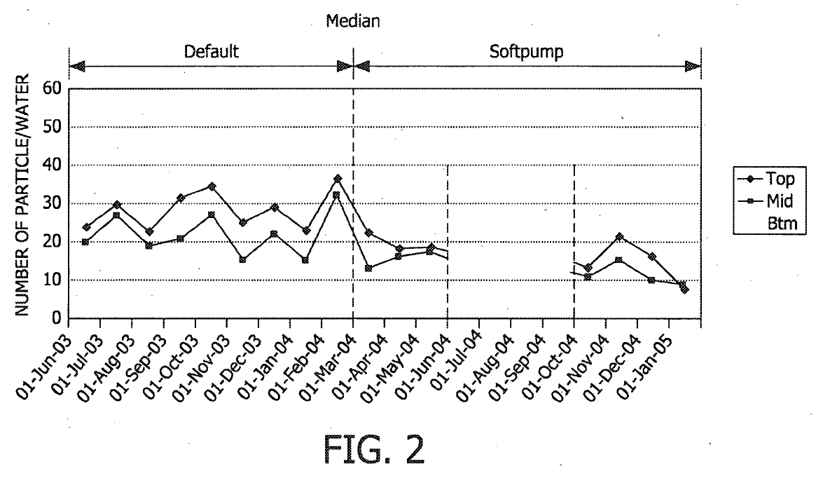

FIG. 2 shows a diagram of the median particle reduction performance over a couple of months. The vertical axis indicates the number of particles that were counted on a wafer after a processing. This was done with test wafers placed in a top (TOP) and a middle (MID) part of the process chamber 2. In the left part of the diagram the median particle performance is shown without pumping with a constant gas flow value. In the right part of the diagram, the median particle performance when pumping with a constant value of gas flow is shown. In the months June to October 2004 other measurements were taken which are not relevant for the present invention. As can be seen, there is a reduction in median particle performance noticeable when the gas flow during pumping down from atmospheric pressure to a low-pressure range in the processing chamber is constant. Therefore, the amount of particle bursts that damage the wafers 5 in the processing chamber 2 is decreased as well.

Although an illustrative embodiment of the present invention has been described in greater detail with reference to the accompanying drawing, it is to be understood that the invention is not limited to the embodiment. Various changes or modifications may be effected by one skilled in the art without departing from the scope or the spirit of the invention as defined in the claims. For example, the pressure gauge 11 can be omitted when the control has a memory in which a pumping down velocity profile for that specific process chamber has been stored. Further, it is possible to connect the second pump 4 also with the pipe extending between the first pump 3 and the first valve 8 so that no pressure difference is present over first valve 8 when it is opened.

1. Processing assembly comprising a processing chamber adapted for receiving at least one wafer to be processed, the processing assembly further being provided with a pump being connectable in fluid connection with the processing chamber for maintaining the pressure in the processing chamber in a low pressure range during processing, wherein the processing assembly is provided with a second pump being connectable in fluid connection with the processing chamber for lowering the pressure from a relatively high pressure, to the low pressure range, wherein gas flow in the processing chamber during lowering the pressure has a constant value.

2. Processing assembly according to claim 1, wherein the constant value of the gas flow is the product of pumping velocity of the second pump and the pressure in said processing chamber.

3. Processing assembly according to claim 1, wherein the processing assembly is provided with a control for controlling the first pump and the second pump.

4. Processing assembly according to to claim 1, wherein the pumping velocity of the second pump is adjustable by the control depending on the pressure in the processing chamber.

5. Processing assembly according to claim 4, wherein the processing chamber comprises a pressure gauge for measuring the pressure in said chamber, wherein the pressure gauge is able to generate a pressure signal for sending to the control.

6. Processing assembly according to Claim 1, wherein the processing assembly is adapted to change the processing chamber from being in fluid connection with the first pump to being in fluid connection with the second pump and vice versa.

7. Processing assembly according to any of the preceding claims, wherein the control of the second pump is provided with a velocity profile.

8. Method for processing a wafer in a processing assembly, according to claim 1, comprising a processing chamber, wherein a wafer to be processed is provided, wherein the processing assembly further comprises a first pump that is brought in fluid connection with the processing chamber to maintain pressure in the processing chamber in a low pressure range during processing and a second pump that is brought in fluid connection with the processing chamber before processing to pump down the pressure from a relatively high pressure, to the low-pressure range in said chamber, wherein during pumping down, the pumping velocity of the second pump is adjusted to provide a gas flow with a constant value in the processing chamber during pumping down.

9. Method according to claim 8, wherein the constant value of the gas flow is the product of the pressure in the processing room and the pumping velocity of the second pump.

10. Method according to claim 8, wherein the pumping velocity of the second pump adjusted depending on the pressure in the processing chamber, which pressure is measured by a pressure gauge provided in said chamber.
